(19) United States
(12) Patent Application Publication
(10) Pub. No.: US 2013/0299213 A1
(43) Pub. Date: Nov. 14, 2013

(54) ELECTRONIC DEVICE WITH HEAT DISSIPATION DEVICE ASSEMBLY

(71) Applicants: SHIH-YAO LI, Tu-Cheng (TW); JUI-WEN HUNG, Tu-Cheng (TW)

(72) Inventors: SHIH-YAO LI, Tu-Cheng (TW); JUI-WEN HUNG, Tu-Cheng (TW)

(73) Assignee: FOXCONN TECHNOLOGY CO., LTD., Tu-Cheng (TW)

(21) Appl. No.: 13/537,068

(22) Filed: Jun. 29, 2012

(30) Foreign Application Priority Data
May 14, 2012 (TW) 101117099

(51) Int. Cl. F28D 15/04; H05K 7/20

(52) U.S. Cl. 174/252; 165/104.26

(57) ABSTRACT

A heat dissipation device assembly for dissipating heat from an electronic component located on a printed circuit board (PCB), includes a heat dissipation module and a fixing device for fixing the heat dissipation module to the PCB board. The heat dissipation module includes a heat pipe, and the heat pipe includes an evaporating section for directly contacting the electronic component and a condensing section. The fixing device includes a base, and a plurality of latches extending from a bottom surface of the base. The latches cooperatively define a space matching with the evaporating section of the heat pipe and partially receiving the evaporating section. The base abuts on the evaporating section thereby pressing the evaporating section to firmly and directly contact the electronic component.

### BACKGROUND

1. Technical Field

The present disclosure relates to a heat dissipation device assembly.

2. Description of Related Art

As computer industry rapidly develops, electronic components operating at high speed generate excessive heat which must be removed efficiently to ensure normal operation. Typically, a heat dissipation device assembly attached to the electronic component is provided for dissipating the heat.

A conventional heat dissipation device assembly includes a heat pipe and a fin assembly thermally connected to the heat pipe. During the assembly process, the heat pipe is welded to a metal board, and a width of the metal board is larger than that of the heat pipe. The metal board is directly attached to a top surface of the electronic component to work as a heat spreader. The heat generated by the electronic component is firstly transferred to the heat pipe via the metal board, successively to the fin assembly, and finally to the surrounding air. Due to the heat being transferred from the electronic component to the heat pipe via the metal board indirectly, therefore, the heat dissipation efficiency of the heat dissipation device assembly is not sufficient enough.

Therefore, a heat dissipation device assembly capable of overcoming the above described shortcomings are desired.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an assembled, isometric view of a heat dissipation device assembly in accordance with an embodiment of the present disclosure.

FIG. 2 is an exploded view of the heat dissipation device assembly of FIG. 1.

FIG. 3 is an inverted, enlarged view of a fixing device of the heat dissipation device assembly of FIG. 1.

### DETAILED DESCRIPTION

Embodiment of the present heat dissipation device assembly will now be described in detail below and with reference to the drawings.

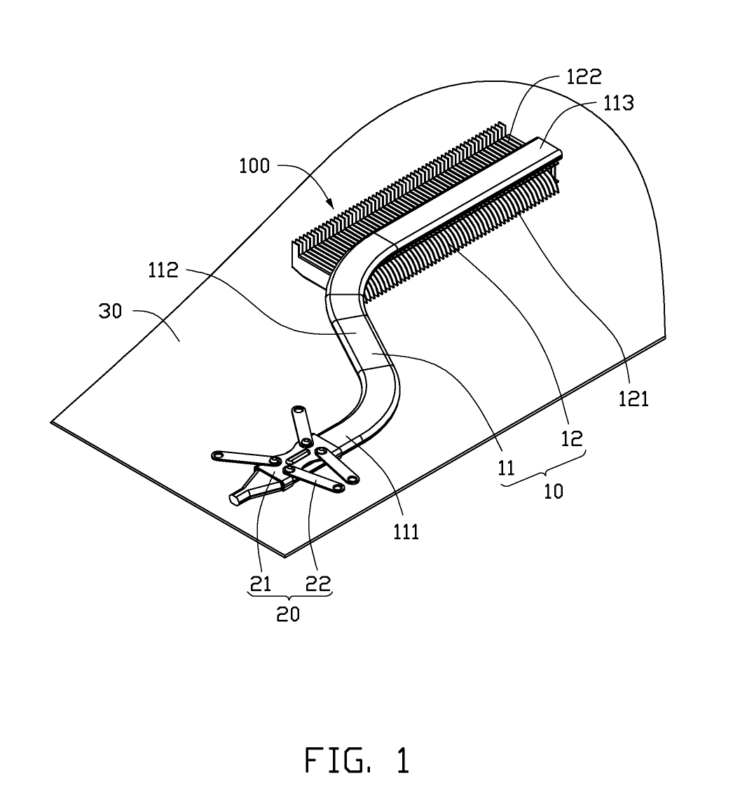

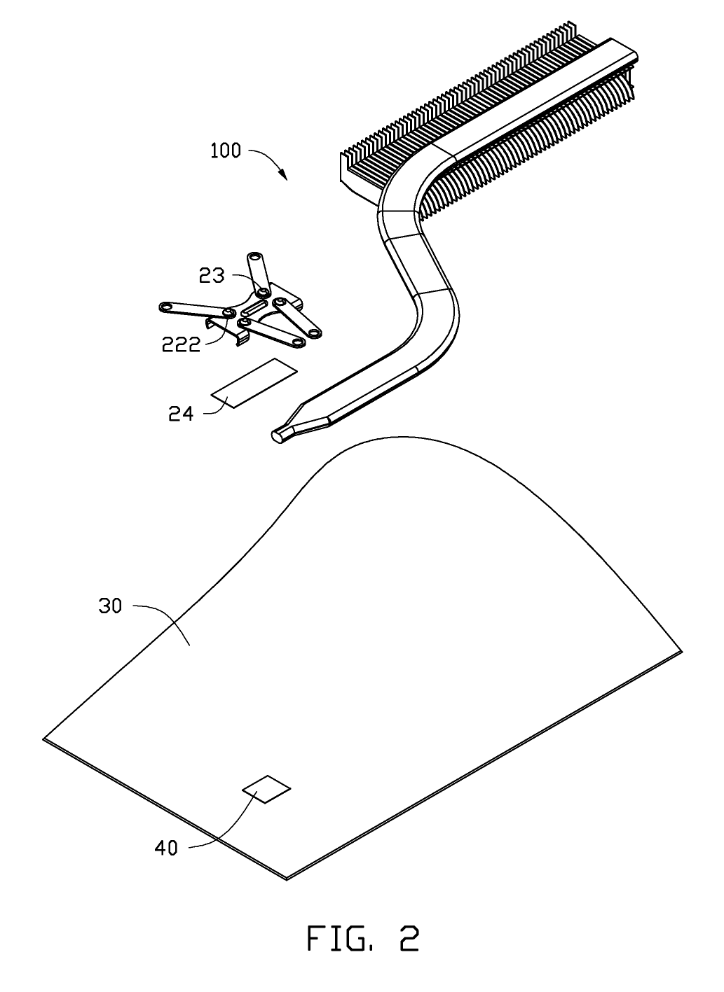

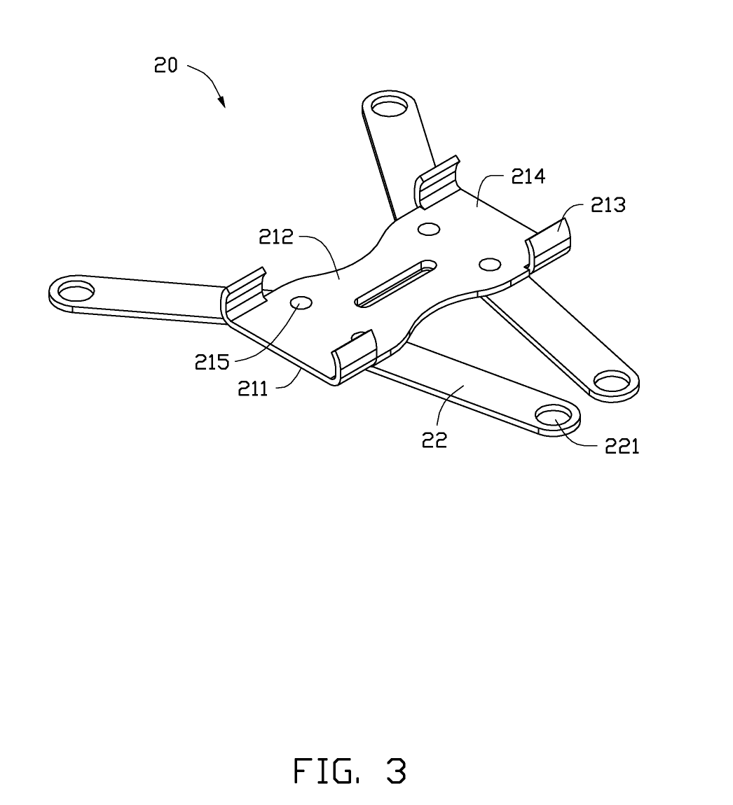

Referring to FIGS. 1 to 3, a heat dissipation device assembly 100, in accordance with an exemplary embodiment of the present disclosure, includes a heat dissipation module 10 and a fixing device 20 for fixing the heat dissipation module 10. The heat dissipation module 10 can be thermally connected to an electronic component 40, and used for dissipating heat generated by the electronic component 40 to the surrounding air.

In this embodiment, the heat dissipation module 10 includes a heat pipe 11 and a fin assembly 12 thermally connected to the heat pipe 11.

The heat pipe 11 is curved, and includes an evaporating section 111, a condensing section 113 and a connecting section 112 interconnecting the evaporating section 111 and the condensing section 113. The evaporating section 111 and the condensing section 113 extend from two opposite ends of the connecting section 112 and along two opposite directions, respectively. The connecting section 112 is curved.

The fin assembly 12 includes a plurality of fins 121 stacked together. The fin assembly 12 defines a top surface 122. The condensing section 113 of the heat pipe 11 is attached to the top surface 122 of the fin assembly 12 for thermally contacting the fin assembly 12.

The fixing device 20 includes a base 21 and a plurality of fixing plates 22 extending from a periphery of the base 21.

The base 21 is a rectangular plate, and includes an upper surface 211 and a bottom surface 212 opposite to the upper surface 211. Four latches 213 extend from the bottom surface 212 of the base 21 for clamping the evaporating section 111 from two lateral sides thereof. The latches 213 cooperatively define a space 214 matching with the evaporating section 111 of the heat pipe 11 for partially receiving the evaporating section 111. The evaporating section 111 of the heat pipe 11 is thermally connected to the base 21, and a bottom surface of the evaporating section 111 of the heat pipe 11 can be configured to directly contact the electronic component 40. In this embodiment, the cross section of the latches 213 is c-shaped.

The fixing plates 22 extend outward from the upper surface 211 of the base 21. Each fixing plate 22 defines a fixing hole 221 at a distal end thereof for fixing the heat pipe 11 to other device, such as a printed circuit board 30 (PCB) which supports the electronic component 40. Preferably, the fixing plate 22 is flexible.

In this embodiment, the fixing plates 22 are riveted on the base 21. Specifically, the base 21 defines a plurality of through holes 215, and the free end of each fixing plate 22 defines a connecting hole 222 thereof. Each through hole 215 is defined corresponding to one of the connecting holes 222 respectively, so the base 21 and the fixing plates 22 are connected together by a plurality of screw bolts 23 penetrating through the through holes 215 and the connecting holes 222. In alteration, the fixing plates 22 can be pivoted to the base 21, or the base 21 and the fixing plates 22 can be integrally formed together.

Preferably, a reinforcement sheet 24 is formed on the bottom surface 212 of the base 21, so the fixing device 20 can be fixed on the evaporating section 111 of the heat pipe 11 more reliably. The reinforcement sheet 24 can prevent the fixing device 20 from slipping or detaching away from the heat dissipation device assembly 100 during conveying. The reinforcement sheet 24 can be double sided adhesives or soldering materials.

In the heat dissipation device assembly 100, the heat pipe 11 can be fixed to a PCB 30 which supporting the electronic component 40 by the fixing plates 22 to apply a downward force, and the evaporating section 111 of the heat pipe 11 can be firmly attached to the electronic component 40 under assistance of the downward force applied by the base 21. Therefore, the evaporating section 111 of the heat pipe 11 directly absorbs the heat generated by the electronic component 40, and transfers the heat to the fin assembly 12 via the connecting section 112 and the condensing section 113, and finally the heat is dissipated to surrounding air by the fin assembly 12. So, the dissipating heat efficiency of the heat dissipation device assembly 100 is improved due to direct heat transfer from the electrical components to the heat pipe 11 without any other heat spreader therebetween. Additional, the omitting of heat spreader is cost-saving.

It is to be understood, the heat pipe 11, the fin assembly 12, the base 21 and the fixing plates 22 of the heat dissipation device assembly 100 are not limited in this embodiment.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A heat dissipation device assembly for dissipating heat from an electronic component located on a printed circuit board, comprising:
a heat dissipation module comprising a heat pipe with an evaporating section for directly contacting the electronic component and a condensing section;
a fixing device for fixing the heat dissipation module to the PCB board, the fixing device comprising a base, and a plurality of latches extending from a bottom surface of the base;
wherein the latches cooperatively define a space matching with the evaporating section of the heat pipe and partially receiving the evaporating section, and the base abuts on the evaporating section thereby pressing the evaporating section to firmly and directly contact the electronic component.

2. The heat dissipation device assembly of claim 1, wherein the cross section of the latch is c-shaped.

3. The heat dissipation device assembly of claim 1, wherein a reinforcement layer is formed between the base of the fixing device and the evaporating section of the heat pipe.

4. The heat dissipation device assembly of claim 3, wherein the reinforcement layer is double sided adhesive.

5. The heat dissipation device assembly of claim 1 further comprising a fin assembly, wherein the condensing section of the heat pipe is thermally connected with the fin assembly.

6. The heat dissipation device assembly of claim 1, wherein the fixing device further comprises a plurality of fixing plates extending from a periphery of the base, and each fixing plate defines a fixing hole at a distal end thereof.

7. The heat dissipation device assembly of claim 6, wherein the fixing plate is flexible.

8. The heat dissipation device assembly of claim 6, wherein the fixing plates are pivoted to the base.

9. The heat dissipation device assembly of claim 6, wherein the base and the fixing plates are integrally formed together.

10. An electronic device, comprising:
an electronic component located on a printed circuit board;
a heat pipe thermally connecting to the electronic component;
a fixing device for fixing the heat pipe to the PCB board, the fixing device comprising a base and a plurality of fixing plates extending from a periphery of the base, a bottom surface of the base defining a plurality of latches extending therefrom;
wherein the plurality of latches clamp edges of the heat pipe, and the base abuts on the heat pipe thereby pressing the heat pipe to firmly and directly contact the electronic component.

11. The electronic device of claim 10, wherein the cross section of the latch is c-shaped.

12. The electronic device of claim 10, wherein a reinforcement layer is formed between the base of the fixing device and the evaporating section of the heat pipe.

13. The electronic device of claim 12, wherein the reinforcement layer is double sided adhesive.

14. The electronic device of claim 10 further comprising a fin assembly, wherein the heat pipe is thermally connected with the fin assembly.

15. The electronic device of claim 10, wherein the fixing device further comprises a plurality of fixing plates extending from a periphery of the base, each fixing plate defines a fixing hole at a distal end thereof.

16. The electronic device of claim 15, wherein the fixing plate is flexible.

17. The electronic device of claim 15, wherein the fixing plates are pivoted to the base.

18. The electronic device of claim 15, wherein the base and the fixing plates are integrally formed together.
